(19) United States
(12) Patent Application Publication
(10) Pub. No.: US 2025/0006771 A1
(43) Pub. Date: Jan. 2, 2025

(54) IMAGE SENSOR

(71) Applicant: SAMSUNG ELECTRONICS CO., LTD., Suwon-si (KR)

(72) Inventors: Junghyun Kim, Suwon-si (KR); Jonghoon Park, Suwon-si (KR); Yun Ki Lee, Suwon-si (KR)

(73) Assignee: SAMSUNG ELECTRONICS CO., LTD., Suwon-si (KR)

(21) Appl. No.: 18/746,889

(22) Filed: Jun. 18, 2024

(30) Foreign Application Priority Data
Jun. 27, 2023 (KR) 10-2023-0082673

(51) Int. Cl. H01L 27/146

(52) U.S. Cl. CPC H01L 27/14645; H01L 27/14621; H01L 27/14627; H01L 27/1463

(57) ABSTRACT

An image sensor includes a first sub-pixel group including a plurality of first unit pixels, a first color filter, a first micro lens at least partially overlapping the plurality of first unit pixels, a second sub-pixel group including a plurality of second unit pixels, a second color filter, a second micro lens at least partially overlapping the plurality of second unit pixels, a third sub-pixel group including a plurality of third unit pixels, a third color filter, a third micro lens at least partially overlapping the plurality of third unit pixels, a first dead zone in which the first micro lens does not overlap the first sub-pixel group, a second dead zone in which the second micro lens does not overlap the second sub-pixel group, and a third dead zone in which the third micro lens does not overlap the third sub-pixel group.

### CROSS-REFERENCE TO RELATED APPLICATION

This application is based on and claims priority to Korean Patent Application No. 10-2023-0082673, filed on Jun. 27, 2023, in the Korean Intellectual Property Office, the disclosure of which is incorporated herein by reference its entirety.

### BACKGROUND

### 1. Field

Example embodiments of the disclosure relate to an image sensor.

### 2. Description of Related Art

A pixel may be divided into an anode area that receives light and a cathode area that does not receive light. A micro lens may serve to collect the inflowing light to the anode area. This structure increases a pixel sensitivity and reduces a pixel noise caused by the structure of the object to be photographed.

On the other hand, when using the micro lens, the angle of the incident light should be included within a predetermined angle (chief ray angle (CRA)) such that the light may reach the anode area. If the angle of the inflowing light is outside the CRA, shadows may occur in the pixel. In addition, since the wavelengths of each of red, green, and blue lights are different, focal points where the light converges after each of the red, green, and blue lights passes through the micro lens are different from each other. In addition, a channel difference problem, which the light passing through the micro lens enters other adjacent pixels instead of the corresponding pixel depending on the refraction angle, may occur.

Information disclosed in this Background section has already been known to or derived by the inventors before or during the process of achieving the embodiments of the present application, or is technical information acquired in the process of achieving the embodiments. Therefore, it may contain information that does not form the prior art that is already known to the public.

### SUMMARY

One or more example embodiments of the disclosure provide an image sensor that has the same focus regardless of a type of an incident light and allows light passing through a micro lens to enter a corresponding pixel.

Additional aspects will be set forth in part in the description which follows and, in part, will be apparent from the description, or may be learned by practice of the presented embodiments.

According to an aspect of an example embodiment, an image sensor may include a first sub-pixel group including a plurality of first unit pixels, a first color filter, a first micro lens at least partially overlapping the plurality of first unit pixels, a second sub-pixel group including a plurality of second unit pixels, a second color filter, a second micro lens at least partially overlapping the plurality of second unit pixels, a third sub-pixel group including a plurality of third unit pixels, a third color filter, a third micro lens at least partially overlapping the plurality of third unit pixels, a first dead zone in which the first micro lens does not overlap the first sub-pixel group, a second dead zone in which the second micro lens does not overlap the second sub-pixel group, and a third dead zone in which the third micro lens does not overlap the third sub-pixel group, where a height of the first micro lens, a height of the second micro lens, and a height of the third micro lens are substantially the same, and where at least one of a size of the first dead zone, a size of the second dead zone, and a size of the third dead zone is different from at least one of the other of the size of the first dead zone, the size of the second dead zone, and the size of the third dead zone.

According to an aspect of an example embodiment, an image sensor may include a substrate, a plurality of photodiodes in the substrate, the plurality of photodiodes including a first photodiode, a second photodiode and a third photodiode, a first sub-pixel group including a plurality of first unit pixels, a first color filter on the first photodiode, a first micro lens at least partially overlapping the plurality of first unit pixels, a second sub-pixel group including a plurality of second unit pixels, a second color filter on the second photodiode, a second micro lens at least partially overlapping the plurality of second unit pixels, a third sub-pixel group including a plurality of third unit pixels, a third color filter on the third photodiode, a third micro lens overlapping the plurality of third unit pixels, a first dead zone in which the first micro lens does not overlap the first sub-pixel group, a second dead zone in which the second micro lens does not overlap the second sub-pixel group, and a third dead zone in which the third micro lens does not overlap the third sub-pixel group, where a height of the first micro lens, a height of the second micro lens, and a height of the third micro lens are substantially the same, and at least one of a size of the first dead zone, a size of the second dead zone, and a size of the third dead zone is different from at least one of the other of the size of the first dead zone, the size of the second dead zone, and the size of the third dead zone.

According to an aspect of an example embodiment, an image sensor may include a substrate, a plurality of photodiodes in the substrate, the plurality of photodiodes including a first photodiode, a second photodiode, a third photodiode, and a fourth photodiode, a first sub-pixel group including a plurality of first unit pixels, a first color filter on the first photodiode, a first micro lens at least partially overlapping the plurality of first unit pixels, a second sub-pixel group including a plurality of second unit pixels, a second color filter on the second photodiode, a second micro lens at least partially overlapping the plurality of second unit pixels, a third sub-pixel group including a plurality of third unit pixels, a third color filter on the third photodiode, a third micro lens overlapping the plurality of third unit pixels, a fourth sub-pixel group including a plurality of fourth unit pixels, a fourth color filter on the fourth photodiode, a fourth micro lens at least partially overlapping the plurality of fourth unit pixels, a first dead zone in which the first micro lens does not overlap the first sub-pixel group, a second dead zone in which the second micro lens does not overlap the second sub-pixel group, a third dead zone in which the third micro lens does not overlap the third sub-pixel group, and a fourth dead zone in which the fourth micro lens does not overlap the fourth sub-pixel group, where a height of the first micro lens, a height of the second micro lens, a height of the third micro lens, and a height of the fourth micro lens are substantially the same, and at least one of a size of the first dead zone, a size of the second dead zone, a size of the third dead zone, and a size of the fourth dead zone is different from at least one of the other of the size of the first dead zone, the size of the second dead zone, the size of the third dead zone, and the size of the fourth dead zone.

### BRIEF DESCRIPTION OF DRAWINGS

The above and other aspects, features, and advantages of certain example embodiments of the present disclosure will be more apparent from the following description taken in conjunction with the accompanying drawings, in which:

FIG. 1 is a block diagram illustrating an image sensor according to one or more embodiments;

FIG. 2 is a circuit diagram illustrating a function of a pixel of FIG. 1 according to one or more embodiments;

FIG. 3 is a plan view illustrating a pixel array of FIG. 1 according to one or more embodiments;

FIG. 4 is a cross-sectional view taken along a line I-I′ of FIG. 3 according to one or more embodiments;

FIG. 5 is a cross-sectional view taken along a line I-I′ of FIG. 3 according to one or more embodiments;

FIG. 6 is a plan view illustrating a structure in which one micro lens is formed for every 2×2 pixel according to one or more embodiments;

FIG. 7 is a plan view illustrating a structure in which one micro lens is formed for every 3×3 pixel according to one or more embodiments;

FIG. 8 is a plan view illustrating a structure in which one micro lens is formed for every 4×4 pixel according to one or more embodiments;

FIG. 9 is an enlarged plan view of an area M of FIG. 3, illustrating an example of a sub-pixel group including unit pixels arranged in a 2×2 form based on a color filter according to one or more embodiments;

FIG. 10 is a cross-sectional view taken along a line II-II′ of FIG. 9 according to one or more embodiments;

FIG. 11 is an enlarged plan view of an area M of FIG. 3, illustrating an example of a sub-pixel group including unit pixels arranged in a 2×2 form based on a color filter RGGB according to one or more embodiments;

FIG. 12 is a cross-sectional view taken along a line III-III′ of FIG. 11 according to one or more embodiments;

FIG. 13 is an enlarged plan view of an area M of FIG. 3, illustrating an example of a sub-pixel group including unit pixels arranged in a 2×2 form based on a color filter RGGB according to one or more embodiments;

FIG. 14 is a cross-sectional view taken along a line IV-IV′ of FIG. 13 according to one or more embodiments;

FIG. 15 to FIG. 17 are enlarged plan views of an area M of FIG. 3, illustrating various examples of a sub-pixel group including unit pixels arranged in a 3×3 form based on a color filter RGGB according to one or more embodiments;

FIG. 18 to FIG. 20 are enlarged plan views of an area M of FIG. 3, illustrating various examples of a sub-pixel group including unit pixels arranged in a 4×4 form based on a color filter RGGB according to one or more embodiments;

FIG. 21 to FIG. 23 are enlarged plan views of an area M of FIG. 3, illustrating various examples of a sub-pixel group including unit pixels arranged in a 4×4 form based on a color filter RGBW according to one or more embodiments;

FIG. 24 to FIG. 26 are diagrams illustrating various examples for a sub-pixel group according to one or more embodiments; and

FIG. 27 to FIG. 29 are diagrams illustrating various examples for a sub-pixel group according to one or more embodiments.

### DETAILED DESCRIPTION

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms.

As used herein, expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

In order to clarify aspects of the disclosure, parts that are not connected with the description will be omitted, and the same elements or equivalents are referred to by the same reference numerals throughout the specification.

Further, since sizes and thicknesses of constituent members shown in the accompanying drawings are arbitrarily given for better understanding and ease of description, aspects of the disclosure not limited to the illustrated sizes and thicknesses. In the drawings, the thickness of layers, films, panels, areas, etc., are exaggerated for clarity. In the drawings, for better understanding and ease of description, thicknesses of some layers and areas are excessively displayed.

It will be understood that when an element such as a layer, film, area, or substrate is referred to as being “on” another element, it may be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction.

In addition, unless explicitly described to the contrary, the word “comprise”, and variations such as “comprises” or “comprising”, will be understood to imply the inclusion of stated elements but not the exclusion of any other elements.

Further, in the specification, the phrase “on a plane” may refer to an object portion being viewed from above, and the phrase “on a cross-section” may refer to a cross-section taken by vertically cutting an object portion being viewed from the side.

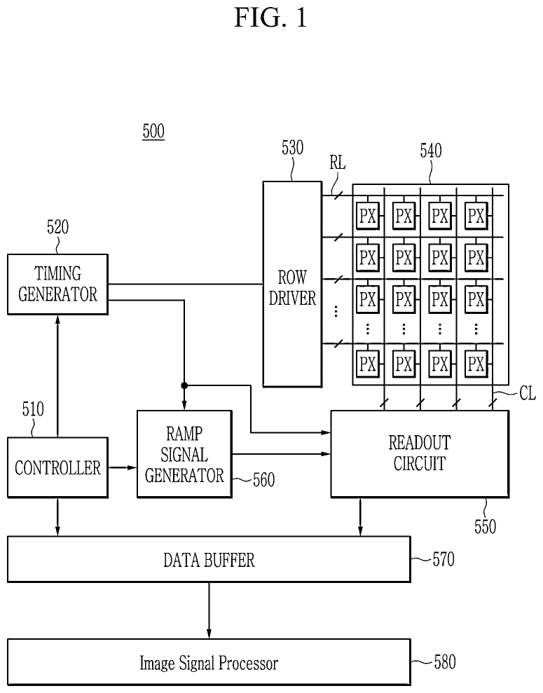

FIG. 1 is a block diagram illustrating an image sensor according to one or more embodiments.

Referring to FIG. 1, an image sensor 500 may include a pixel array 540 and a logic circuit.

The image sensor 500 may generate an image signal by converting light received from the outside into an electric signal. For example, the image sensor 500 may transfer the generated image signal to an image signal processor 580 to be described below.

The image sensor 500 may be mounted on an electronic device having an image or light sensing function. For example, the image sensor 500 may be mounted on an electronic device such as a camera, smartphone, wearable device, Internet of Things (IoT) device, home appliance, tablet personal computer (PC), navigation, drone, and advanced driver assistance system (ADAS). Alternatively, the image sensor 500 may be mounted on an electronic device provided as a component in a vehicle, furniture, manufacturing facility, door, or various measuring devices.

The pixel array 540 may include a plurality of pixels (e.g., pixels PX), a plurality of row lines (e.g., row lines RL), and a plurality of column lines (e.g., column lines CL). For example, a row line RL and a column line CL may be respectively connected to a pixel PX.

The pixels PX may include a photovoltaic device. The photovoltaic device may sense incident light and generate an electric signal (charges) corresponding to the amount of light. The electric signal may correspond to an analog pixel signal. For example, the photovoltaic device PD may be a photodiode, a pinned diode, and the like. For another example, the photovoltaic device may be a single-photon avalanche diode (SPAD) applied to a three-dimensional (3D) sensor pixel.

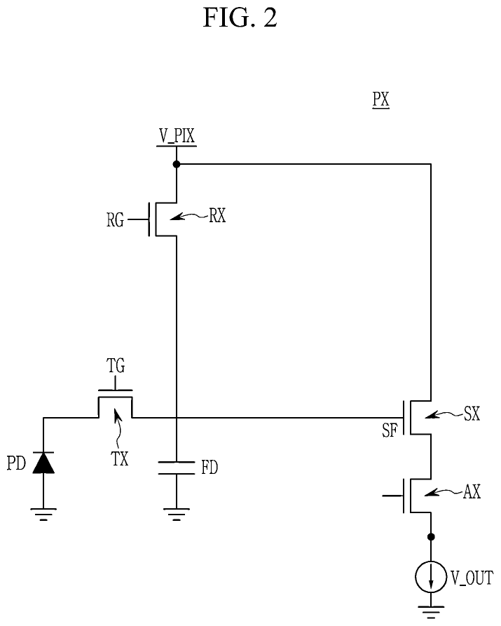

The level of the analog pixel signal output by the photovoltaic device may be proportional to the amount of charges output from the photovoltaic device. That is, the level of the analog pixel signal may be determined according to the amount of light received into the pixel array 540. The various configurations elements constituting a pixel PX are described in FIG. 2 to FIG. 4 in detail.

The plurality of row lines (e.g., row line RL) may be electrically connected to a plurality of pixels (e.g., pixel PX). For example, a control signal output from the row driver 530 to the row line RL may be transmitted to gates of transistors of the plurality of pixels (e.g., pixel PX) connected to the corresponding row line RL.

The plurality of column lines (e.g., column line CL) may be electrically connected to the plurality of pixels (e.g., pixel PX). Specifically, a predetermined column line CL may be positioned to intersect a predetermined row line RL. The plurality of pixel signals output from the plurality of pixels (e.g., pixel PX) may be transmitted to a readout circuit 550 through the plurality of column lines (e.g., column line CL).

In an embodiment, the plurality of pixels (e.g., pixel PX) may be arranged along a plurality of columns and a plurality of rows, and one analog pixel signal may be output for each pixel PX. However, example embodiments are not limited thereto, and numerous variations are possible. For example, the plurality of pixels (e.g., pixel PX) may be grouped in the form of the plurality of columns and the plurality of rows to form one unit pixel group. One unit pixel group may include a plurality of pixels (e.g., pixel PX) arranged in the form of two columns and two rows, and one unit pixel group may output one analog pixel signal.

The logic circuit is a circuit to control the pixel array 540. For example, the logic circuit may include a controller 510, a timing generator 520, the row driver 530, the readout circuit 550, a ramp signal generator 560, and a data buffer 570. For another example, the logic circuit may further include an image signal processor 580. In some embodiments, the image signal processor 580 may be positioned outside of the image sensor 500.

The controller 510 may control an operation timing of the timing generator 520, the row driver 530, the readout circuit 550, the ramp signal generator 560, and the data buffer 570 using control signals.

In an embodiment, the controller 510 may receive a mode signal indicating an imaging mode from an application processor and overall control the image sensor 500 based on the received mode signal. For example, the application processor may determine the imaging mode of the image sensor 500 according to various scenarios such as an illumination of the imaging environment, a user's resolution setting, a sensing or learned state, and provide the determined result to the controller 510 as a mode signal.

The controller 510 may control the plurality of pixels (e.g., pixel PX) to output the pixel signals according to the imaging mode. The pixel array 540 may output the pixel signal for each of the plurality of pixels (e.g., pixel PX) or the pixel signal for some of the plurality of pixels (e.g., pixel PX). The readout circuit 550 may sample and process the pixel signals received from the pixel array 540.

The timing generator 520 may generate a signal serving as a reference for the operation timing of components of the image sensor 500. The timing generator 520 may control the timing of the row driver 530, the readout circuit 550, and the ramp signal generator 560. The timing generator 520 may provide a control signal for controlling the timing of the row driver 530, the readout circuit 550, and the ramp signal generator 560.

The row driver 530 may generate a control signal for driving the pixel array 540 in response to the control signal of the timing generator 520 and provide the control signal to the plurality of pixels (e.g., pixel PX) of the pixel array 540 through the plurality of row line RL.

In an embodiment, the row driver 530 may control the pixel PX to sense incident light by a row line unit. The row line unit may include at least one row line RL. For example, the row driver 530 may generate a transfer control signal for controlling a transfer transistor, a reset control signal for controlling a reset transistor, a selection control signal for controlling a selection transistor, and the like, and provide the generated signals to the pixel array 540.

The readout circuit 550 may convert the pixel signal (or the electric signal) from the pixel PX connected to the row line RL selected from among the plurality of pixels (e.g., pixel PX) into a pixel value representing the amount of light in response to the control signal from the timing generator 520.

The readout circuit 550 may convert the pixel signal output through the corresponding column line CL into a pixel value. For example, the readout circuit 550 may convert a pixel signal into the pixel value by comparing the ramp signal and the pixel signal. The pixel value may be an image data having a plurality of bits. Specifically, the readout circuit 550 may include a selector, a plurality of comparators, and a plurality of counter circuits.

The ramp signal generator 560 may generate a reference signal and transmit the reference signal to the readout circuit 550. The ramp signal generator 560 may include a current source, a resistor, and a capacitor. By adjusting the current size of the variable current source or the resistance value of the variable resistor to control the ramp voltage, which is the voltage applied to the ramp resistance, the ramp signal generator 560 may generate a plurality of ramp signals that fall or rise with a slope determined according to the current size of the variable current source or the resistance value of the variable resistor.

The data buffer 570 may store the pixel values of the plurality of pixels (e.g., pixel PX) connected to the selected column line CL transmitted from the readout circuit 550 and output the stored pixel values in response to an enable signal from the controller 510.

The image signal processor 580 may perform an image signal processing on the image signal received from the data buffer 570. For example, the image signal processor 580 may receive a plurality of image signals from the data buffer 570 and synthesize the received image signals to generate one image.

Hereinafter, various configurations elements constituting the pixel PX will be described in detail with reference to FIG. 2 to FIG. 4.

FIG. 2 is a circuit diagram illustrating a function of a pixel of FIG. 1 according to one or more embodiments.

Referring to FIG. 2, a unit pixel PX may output an electric signal (charges) corresponding to the amount of light from an incident light. According to an embodiment, the pixel PX may include a photovoltaic device PD, a transfer transistor TX, a floating diffusion zone FD, a reset transistor RX, a source follower transistor SX, and a selection transistor AX.

The photovoltaic device PD may generate charge by sensing an external image (or light). For example, the photovoltaic device PD may include an organic photodiode.

When the photovoltaic device PD is composed of an organic photodiode, the photovoltaic device PD may include a first electrode and a second electrode disposed in parallel with each other, and an organic light conversion layer provided therebetween. The organic light conversion layer may generate charges by accepting light of a predetermined wavelength band. The photovoltaic device PD may be a photodiode, a photo transistor, a photo gate, a pinned photodiode or combinations thereof, but embodiments are not limited thereto.

The transfer transistor TX may transfer charges generated in the photovoltaic device PD to the floating diffusion zone FD. The transfer gate TG, which is the gate of the transfer transistor TX, may have one end connected to the photovoltaic device PD and the other end connected to the floating diffusion zone FD. For example, the transfer transistor TX may be controlled by a transfer signal provided from the row driver 130. The transfer transistor TX may electrically connect the photovoltaic device PD and the floating diffusion zone FD based on the transfer signal.

The floating diffusion zone FD may store the charges generated in the photovoltaic device PD. For example, the floating diffusion zone FD may function as a drain of the transfer transistor TX. In addition, the floating diffusion zone FD may be electrically connected to a source gate SF, which is the gate of the source follower transistor SX.

The reset transistor RX may reset the voltage level of the floating diffusion zone FD to a reset level. A reset gate RG, which is the gate of the reset transistor RX, may have one end connected to a power supply providing pixel voltage V_PIX and the other end connected to the floating diffusion zone FD. For example, the reset transistor RX may be controlled by the reset control signal provided from the row driver 530. The reset transistor RX may reset the voltage level of the floating diffusion zone FD to the reset level based on the reset control signal.

The source follower transistor SX may output the charge level of the floating diffusion zone FD as the output voltage V_OUT using the pixel voltage V_PIX. The source gate SF, which is the gate of the source follower transistor SX, may have one end connected to a power supply providing the pixel voltage V_PIX, and the other end connected to the selection transistor AX.

The selection transistor AX may output the output voltage V_OUT received from source follower transistor SX to the column line CL connected to the selection transistor AX. At this time, the output voltage V_OUT may be provided to the readout circuit 550. For example, selection transistor AX may be controlled by a selection signal provided from row driver 530. The source terminal of the selection transistor AX may be connected to the drain terminal of the source follower transistor SX, and the drain terminal of the selection transistor AX may be connected to the column line CL.

The operation of the image sensor 500 according to the embodiment is described with reference to FIG. 1 as follows. First, in a state where light is blocked, the pixel voltage V_PIX is applied to the drain of the reset transistor RX and the drain of the source follower transistor SX, and the reset transistor RX is turned on to discharge the remaining charges in the floating diffusion zone FD.

After that, the reset transistor RX is controlled to be turned off, and light from the outside is incident to the photovoltaic device PD. Then, electron-hole pairs are created in the photovoltaic device PD. Holes are accumulated by moving to the P-type impurity area of the photovoltaic device PD, and electrons are accumulated by moving to the N-type impurity area.

When the transfer transistor TX is controlled to be turned on, charges such as electrons and holes are transferred to the floating diffusion zone FD and accumulated.

Thereafter, the gate bias of the source follower transistor SX changes in proportion to the amount of the charges accumulated in the floating diffusion zone FD, thereby changing the source potential of the source follower transistor SX. If the selection transistor AX is controlled to be turned on, a signal by the charged may be read by the column line CL.

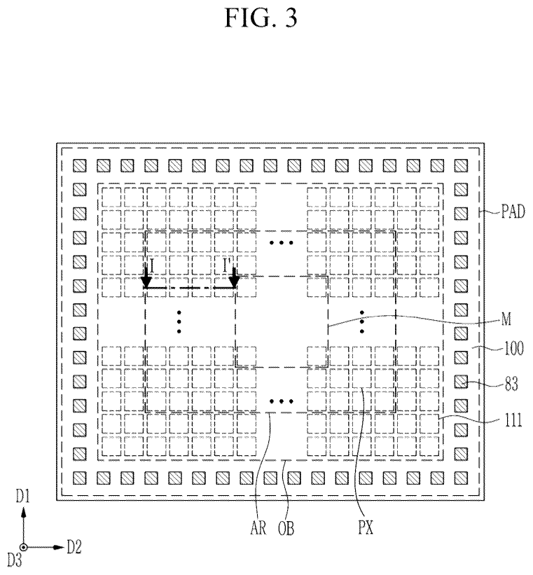

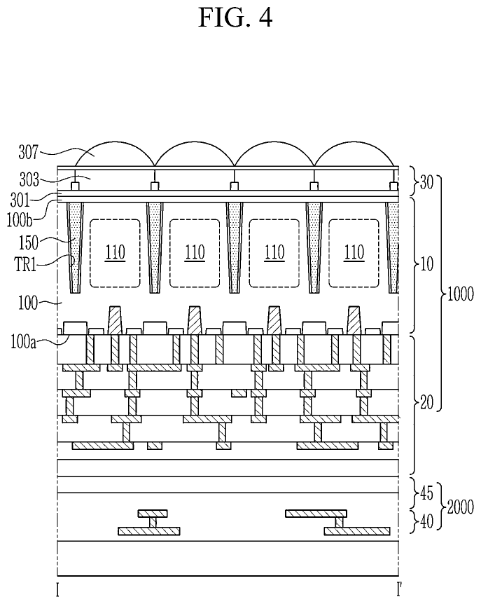

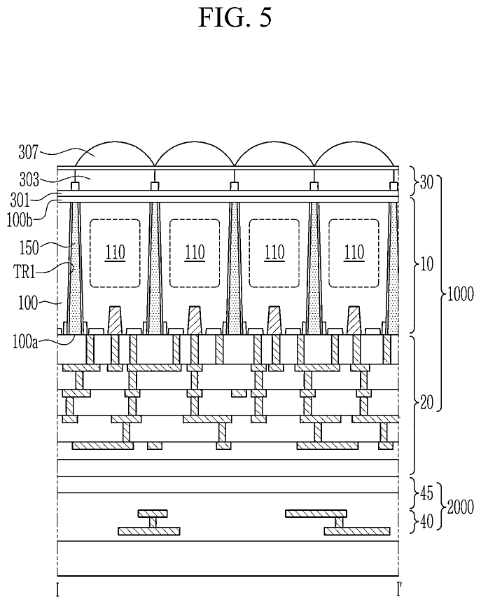

FIG. 3 is a plan view illustrating a pixel array of FIG. 1 according to one or more embodiments. FIG. 4 is a cross-sectional view taken along a line I-I′ of FIG. 3 according to one or more embodiments. FIG. 5 is a cross-sectional view taken along a line I-I′ of FIG. 3 according to one or more embodiments.

FIG. 4 and FIG. 5 differs only in the manufacturing process and structure of a pixel isolation pattern 150 to be described below, and all other constituent elements are substantially equivalent. In the following, FIG. 4 is described as a reference, and differences from FIG. 5 will be further explained.

Referring to FIGS. 3 to 5, an image sensor may include a sensor chip 1000 and a logic chip 2000. The sensor chip 1000 may include a photoelectric conversion layer 10, a first wiring layer 20, and a light transmission layer 30. The photoelectric conversion layer 10 may include a first substrate 100, a pixel isolation pattern 150, and a photovoltaic device PD provided within the first substrate 100. Light incident from the outside may be converted into an electrical signal in the photovoltaic device PD.

The first substrate 100 may include a pixel array area AR, an optical black area OB, and a pad area PAD in a term of a flat area. The pixel array area AR may be disposed in the center portion of the first substrate 100 in terms of flat area. The pixel array area AR may include a plurality of unit pixels (e.g., unit pixels PX). The unit pixels PX may output a photoelectric signal from an incident light. The unit pixels PX may include columns and rows, and may be arranged two-dimensionally. The columns may be parallel to the first direction D1. The rows may be parallel to the second direction D2. In some embodiments, the first direction D1 may be parallel to the first surface 100a and the second surface 100b of the first substrate 100. The second direction D2 may be parallel to the first surface 100a and the second surface 100b of the first substrate 100, and may be substantially perpendicular to the first direction D1. The third direction D3 may be substantially perpendicular to the first surface 100a of the first substrate 100.

The pad area PAD may be provided on the edge portion of the first substrate 100, and in a term of a flat area may surround the pixel array area AR. The second pad terminals 83 may be provided on the pad area PAD. The second pad terminals 83 may output electrical signals generated from unit pixels PX to the outside. Alternatively, an external electrical signal or voltage may be transferred to the unit pixels PX through the second pad terminals 83. Since the pad area PAD is disposed on the edge of the first substrate 100, the second pad terminals 83 may be easily connected to the outside.

The optical black area OB may be disposed between the pixel array area AR and the pad area PAD of the first substrate 100. The optical black area OB may surround or at least partially surround the pixel array area AR in a term of a flat area. The optical black area OB may include a plurality of dummy areas 111. The signal generated in the dummy area 111 may be used as an information to remove a process noise later.

Referring to FIG. 4, the first substrate 100 may have a first surface 100a and a second surface 100b that are opposite to each other. Light may be incident on the second surface 100b of the first substrate 100. The first wiring layer 20 may be disposed on the first surface 100a of the first substrate 100, and the light transmission layer 30 may be disposed on the second surface 100b of the first substrate 100. The first substrate 100 may be a semiconductor substrate or a silicon insulator (SOI) substrate. The semiconductor substrate, for example, may include a silicon substrate, a germanium substrate, or a silicon-germanium substrate. The first substrate 100 may include an impurity of a first conductivity type. For example, the impurity of the first conductivity type may include a P-type impurity such as aluminum (Al), boron (B), indium (In) and/or gallium (Ga).

The first substrate 100 may include a plurality of unit pixels (e.g., unit pixel PX) defined by the pixel isolation pattern 150. The plurality of unit pixel (e.g., unit pixel PX) may be arranged in a matrix format along first direction D1 and the second direction D2 intersecting11 each other. The first substrate 100 may include a photoelectric conversion area 110. The photoelectric conversion area 110 may be provided for each unit pixel PX within the first substrate 100. The photoelectric conversion area 110 may perform the same function and role as the photovoltaic device PD (e.g., FIG. 2). The photoelectric conversion area 110 may be an area doped with an impurity of a second conductivity type within the first substrate 100. The impurity of the second conductivity type may have a conductivity type opposite to that of the first conductivity type. The impurity of the second conductivity type may include an N-type impurity such as phosphorus, arsenic, bismuth, and/or antimony.

The first substrate 100 and the photoelectric conversion area 110 may constitute a photodiode. That is, the photodiode may be formed by a p-n junction between the first substrate 100 of the first conductivity type and the photoelectric conversion area 110 of the second conductivity type. The photoelectric conversion area 110 constituting the photodiode may generate and accumulate photo charges in proportion to the intensity of incident light.

The pixel isolation pattern 150 may be provided within the first substrate 100 and define the unit pixel PX. For example, the pixel isolation pattern 150 may be provided between the unit pixels PX of the first substrate 100. In a term of a flat area, the pixel isolation pattern 150 may have a lattice structure. In a term of a flat area, the pixel isolation pattern 150 may completely surround the unit pixel PX. The pixel isolation pattern 150 may prevent photo charges generated by incident light incident on each of the unit pixels PX from being incident on the adjacent unit pixels PX by a random drift. That is, the pixel isolation pattern 150 may prevent a crosstalk between the unit pixels PX.

The pixel isolation pattern 150 may be provided within a first trench TR1. The first trench TR1 may be recessed from the second surface 100b of the first substrate 100. The pixel isolation pattern 150 may extend from the second surface 100b of the first substrate 100 toward the first surface 100a. The pixel isolation pattern 150 may be a deep trench isolation (DTI). The pixel isolation pattern 150 may be formed of metal, polysilicon or impurity doped polysilicon (doped polysilicon), but the range of the present disclosure is not limited thereto.

Referring to FIG. 4, the pixel isolation pattern 150 according to an embodiment may be formed of a backside deep trench isolation (BDTI) process. The pixel isolation pattern 150 may be a DTI structure having a vertically deeply recessed shape from the rear surface of the first substrate 100 (that is, from the second surface 100b through the BDTI process). The pixel isolation pattern 150 formed by the BDTI process is spaced apart from the first surface 100a by a predetermined interval, and the vertical height thereof may be smaller than the vertical thickness of the first substrate 100. In addition, the width of the pixel isolation pattern 150 may be formed to become narrower toward the direction from the second surface 100b to the first surface 100a.

Referring to FIG. 5, the pixel isolation pattern 150 may be formed of a frontside deep trench isolation (FDTI) process. The pixel isolation pattern 150 may have a DTI structure having a vertically deep groove from the first surface 100a, which is the front surface of the first substrate 100, to the second surface 100b, which is the rear surface, through the FDTI process. The pixel isolation pattern 150 formed by the FDTI process may penetrate the first substrate 100. That is, the vertical height of the pixel isolation pattern 150 may be substantially equivalent to the vertical thickness of the first substrate 100. Also, the width of the pixel isolation pattern 150 may be formed to widen in a direction from the second surface 100b to the first surface 100a.

The first wiring layer 20 may include a plurality of insulation layers, a plurality of wires, a plurality of vias, a plurality of contacts, and a plurality of gate contacts. The plurality of insulation layers may include a non-conductive material. For example, the plurality of insulation layers may include a silicon-based insulating material such as silicon oxide, silicon nitride, and/or silicon oxide nitride. A plurality of wires may be vertically connected to any one of the transfer transistors TX, the source follower transistors SX, the reset transistors RX, and the selection transistors AX through a plurality of gate contacts. The plurality of wires may be vertically connected to the floating diffusion zone FD and the extrinsic area through the plurality of contacts. The plurality of contacts and the plurality of gate contacts may pass through some insulation layers. The plurality of vias may be provided within the insulation layer. The plurality of vias may electrically connect some wires.

The light transmission layer 30 may include a filter layer 301, a color filter 303, and a micro lens 307. The light transmission layer 30 may condense and filter light incident from the outside and transmit the light to the photoelectric conversion layer 10.

The filter layer 301 may be interposed between the color filter 303 and the second surface 100b of the first substrate 100. The filter layer 301 may cover or at least partially cover the upper surface of the second surface 100b of the first substrate 100. That is, the upper surface of the filter layer 301 may contact the bottom surface of the color filter 303, and the bottom surface of the filter layer 301 may contact the upper surface of the second surface 100b of the first substrate 100. However, embodiments are not limited thereto, and another layer may be further positioned between the filter layer 301 and the color filter 303, and another layer may be further positioned between the second surface 100b of the first substrate 100 and the filter layer 301.

The filter layer 301 may transmit light of a specific wavelength band and block light of the remaining wavelength bands. The filter layer 301 may transmit light having a specific central wavelength, and has a Fabry-Perot structure in which a resonant layer (e.g., a band pass filter, etc.) is provided between two reflection layers. The center wavelength and the wavelength band of light passing through the band pass filter may be determined according to the reflection band of the reflection layers and the characteristics of the resonant layer.

The color filter 303 may be positioned on the filter layer 301. A plurality of color filters may be positioned to correspond to each of the photovoltaic devices PD. The plurality of color filters may include a first color filter, a second color filter, a third color filter, and a fourth color filter. For example, the first color filter may be a red color filter, the second color filter may be a green color filter, the third color filter may be a blue color filter, and the fourth color filter may be a white color filter.

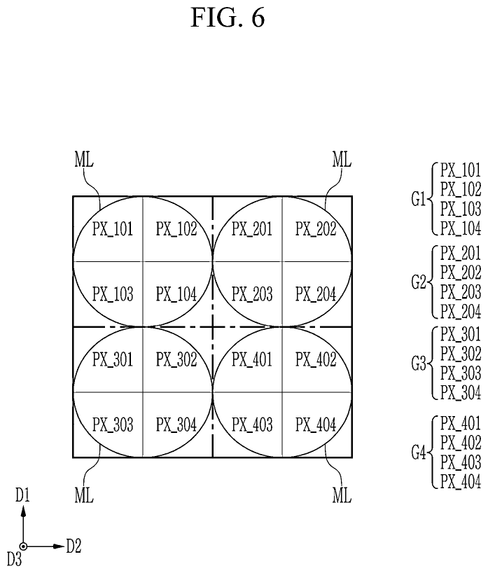

The color filter 303 may be positioned corresponding to each plurality of pixels PX. According to an embodiment, each of the first color filter, the second color filter, the third color filter, and the fourth color filter on a plane may form various patterns. This is described in detail together with reference to FIG. 6 to FIG. 23.

The micro lens 307 positioned on the color filter 303 may condense light incident from the outside. According to an embodiment, the plurality of unit pixels may share one micro lens 307. In addition, the size of the dead zone may vary depending on the type of the overlapping color filter 303, but the height of the micro lens 307 may be the same even if the type of overlapping color filter 303 is different.

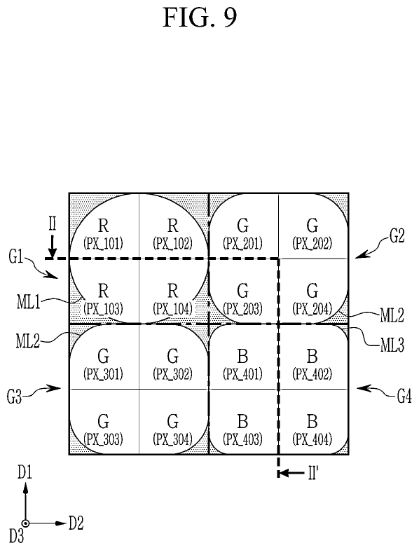

The dead zone may be an area that does not overlap the micro lens 307 among the areas of the sub-pixel group including a plurality of unit pixels. The dead zone may be defined as a dead line. Hereinafter, the dead zone and the like are described in more detail in FIG. 9 to FIG. 23.

Referring to FIG. 4, the image sensor may further include a logic chip 2000. The logic chip 2000 may be stacked on the sensor chip 1000. The logic chip 2000 may include a second substrate 40 and a second wiring layer 45. The second wiring layer 45 may be interposed between the first wiring layer 20 and the second substrate 40.

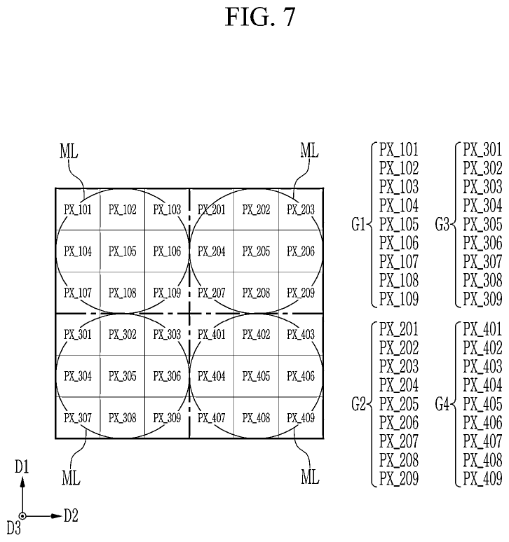

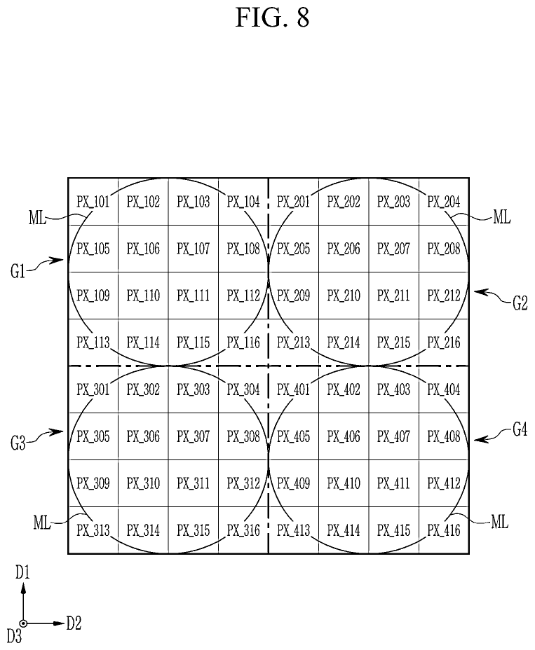

FIG. 6 is a plan view illustrating a structure in which one micro lens is formed for every 2×2 pixel according to one or more embodiments. FIG. 7 is a plan view illustrating a structure in which one micro lens is formed for every 3×3 pixel according to one or more embodiments. FIG. 8 is a plan view illustrating a structure in which one micro lens is formed for every 4×4 pixel according to one or more embodiments.

Referring to FIG. 6, according to an embodiment, a plurality of unit pixels arranged in a 2×2 form in first direction D1 parallel to first surface 100a of first substrate 100 and the second direction D2 parallel to first surface 100a and perpendicular to first direction D1 may constitute a sub-pixel group. In FIG. 6, four sub-pixel groups G1, G2, G3, and G4 are shown, but it is not limited thereto, and the image sensor 500 may include various numbers of sub-pixel groups.

The first sub-pixel group G1 may include first to fourth unit pixels PX_101, PX_102, PX_103, and PX_104. The second sub-pixel group G2 may include first to fourth unit pixels PX_201, PX_202, PX_203, and PX_204. The third sub-pixel group G3 may include first to fourth unit pixels PX_301, PX_302, PX_303, and PX_304. The fourth sub-pixel group G4 may include first to fourth unit pixels PX_401, PX_402, PX_403, and PX_404. Each of the first sub-pixel group G1, the second sub-pixel group G2, the third sub-pixel group G3, and the fourth sub-pixel group G4 may overlap one micro lens ML.

Referring to FIG. 7, according to an embodiment, a plurality of unit pixels arranged in a 3×3 form in first direction D1 parallel to first surface 100a of first substrate 100 and the second direction D2 parallel to first surface 100a and perpendicular to first direction D1 may constitute a sub-pixel group. In FIG. FIG. 7, four sub-pixel groups G1, G2, G3, and G4 are shown, but example embodiments are not limited thereto, and the image sensor 500 may include various numbers of sub-pixel groups.

The first sub-pixel group G1 may include first to ninth unit pixels PX_101, PX_102, PX_103, and PX_104, PX_105, PX_106, PX_107, PX_108, and PX_109. The second sub-pixel group G2 may include first to ninth unit pixels PX_201, PX_202, PX_203, and PX_204, PX_205, PX_206, PX_207, PX_208, and PX_209. The third sub-pixel group G3 may include first to ninth unit pixels PX_301, PX_302, PX_303, and PX_304, PX_305, PX_306, PX_307, PX_308, and PX_309. The fourth sub-pixel group G4 may include first to ninth unit pixels PX_401, PX_402, PX_403, and PX_404, PX_405, PX_406, PX_407, PX_408, and PX_409. Each of the first sub-pixel group G1, the second sub-pixel group G2, the third sub-pixel group G3, and the fourth sub-pixel group G4 may overlap one micro lens ML.

Referring to FIG. 8, according to an embodiment, a plurality of unit pixels arranged in a 4×4 form in first direction D1 parallel to first surface 100a of first substrate 100 and the second direction D2 parallel to first surface 100a and perpendicular to first direction D1 may constitute a sub-pixel group. In FIG. FIG. 8, four sub-pixel groups G1, G2, G3, and G4 are shown, but example embodiments are not limited thereto, and the image sensor 500 may include various numbers of sub-pixel groups.

The first sub-pixel group G1 may include first to sixteenth unit pixels PX_101, PX_102, PX_103, and PX_104, PX_105, PX_106, PX_107, PX_108, PX_109, PX_110, PX_111, PX_112, PX_113, PX_114, PX_115, and PX_116. The second sub-pixel group G2 may include first to sixteenth unit pixels PX_201, PX_202, PX_203, and PX_204, PX_205, PX_206, PX_207, PX_208, PX_209, PX_210, PX_211, PX_212, PX_213, PX_214, PX_215, and PX_216. The third sub-pixel group G3 may include first to sixteenth unit pixels PX_301, PX_302, PX_303, and PX_304, PX_305, PX_306, PX_307, PX_308, PX_309, PX_310, PX_311, PX_312, PX_313, PX_314, PX_315, and PX_316. The fourth sub-pixel group G4 may include first to sixteenth unit pixels PX_401, PX_402, PX_403, and PX_404, PX_405, PX_406, PX_407, PX_408, PX_409, PX_410, PX_411, PX_412, PX_413, PX_414, PX_415, and PX_416. Each of the first sub-pixel group G1, the second sub-pixel group G2, the third sub-pixel group G3, and the fourth sub-pixel group G4 may overlap one micro lens ML.

In FIG. 6 to FIG. 8, the sub-pixel groups including the plurality of unit pixels arranged in the 2×2, 3×3, 4×4 shapes in the first direction D1 and the second direction D2 and overlapping one micro lens ML have been described. According to an embodiment, the dead zone corresponding to the curvature of the overlapping micro lens may be different according to the type of the color filter included in each of the first to fourth sub-pixel groups (G1, G2, G3, and G4). Various embodiments of the sub-pixel group having the different dead zones of the overlapping micro lenses according to the type of the color filter will be described in detail with drawings below.

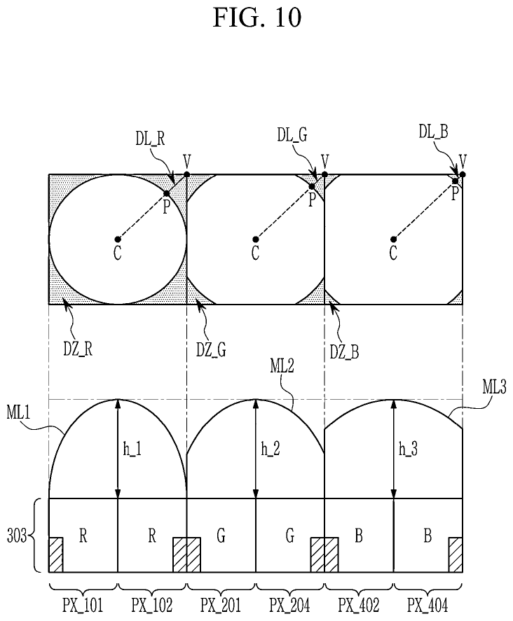

FIG. 9 is an enlarged plan view of an area M of FIG. 3, illustrating an example of a sub-pixel group including unit pixels arranged in a 2×2 form based on a color filter RGGB according to one or more embodiments. FIG. 10 is a cross-sectional view taken along a line II-II′ of FIG. 9 according to one or more embodiments.

Referring to FIG. 9 and FIG. 10, the sub-pixel group may determine the curvature of the overlapping micro lens ML according to the color of the color filter 303. A channel difference phenomenon in which the light passing through the micro lens ML may enter other adjacent pixels PX other than the designated pixel PX may be reduced. In addition, the first micro lens ML1 overlapping the red (R) color filter 303, the second micro lens ML2 overlapping the green (G) color filter 303, the third micro lens ML3 overlapping the blue (B) color filter 303, and the fourth micro lens ML4 overlapping the white (W) color filter 303 may all have substantially the same focus.

According to an embodiment, if the radius is adjusted while the height of the micro lens is fixed, the curvature of the lens may be changed. For example, if the radius is reduced while the height is constant, the curvature of the micro lens may increase. For another example, if the radius is increased while the height is constant, the curvature of the micro lens may decrease.

Referring to FIG. 9 and FIG. 10, the heights of the first micro lens ML1 overlapping the red (R) color filter 303, the second micro lens ML2 overlapping the green (G) color filter 303, and the third micro lens ML3 overlapping the blue (B) color filter 303 may be substantially the same (h_1=h_2=h_3). Also, the first radius of the first micro lens ML1 may be the smallest, the third radius of the third micro lens ML3 may be the largest, and the second radius of the second micro lens ML2 may be larger than the first radius and smaller than the third radius. Referring to FIG. 10, the first curvature of first micro lens ML1 may be the largest, the third curvature of third micro lens ML3 may be the smallest, and the second curvature of second micro lens ML2 may be smaller than the first curvature and may be larger than the third curvature. In this case, the height h of the micro lens may correspond to the maximum vertical length from the bottom surface of the micro lens overlapping the color filter 303 to the circumference.

According to an embodiment, referring to FIG. 10, if the curvature of the micro lens increases, the dead zone and a side of a dead line may be increased. The dead zone may be an area that does not overlap with the micro lens among the areas of the sub-pixel group when the sub-pixel group and the micro lens overlap. The dead line may be the shortest distance between the vertex V of the quadrangle, which is the outer edge of the sub-pixel group, and the circumference, which is the edge of the surface where the micro lens overlaps the color filter of the sub-pixel group.

The size of the dead zone may correspond to the size of the dead line. When the dead line is determined, the size of the dead zone may be also determined. Referring to FIG. 10, the dead line may correspond to the distance between the intersection point P and the vertex V. The intersection P may be an intersection that meets when connecting the vertex V of the quadrangle, which is the outer border of sub-pixel group, and the center C of the circle where the micro lens overlaps with the color filter 303 of the sub-pixel group.

Referring to FIG. 9, in the first sub-pixel group G1, a plurality of first unit pixels PX_101, PX_102, PX_103, and PX_104 may overlap one first micro lens ML1. A plurality of first unit pixels PX_101, PX_102, PX_103, and PX_104 may be arranged with 2×2, and each plurality of first unit pixels PX_101, PX_102, PX_103, and PX_104 may include a color filter 303 of red (R). Hereinafter, the plurality of first unit pixels PX_101, PX_102, PX_103, and PX_104 are described as the plurality of first unit pixels PX_101-PX_104.

In the second sub-pixel group G2, the plurality of second unit pixels PX_201, PX_202, PX_203, and PX_204 may overlap one second micro lens ML2. The plurality of second unit pixels PX_201, PX_202, PX_203, and PX_204 may be arranged with 2×2, and each of the plurality of second unit pixels PX_201, PX_202, PX_203, and PX_204 may include a color filter of green (G). Hereinafter, the plurality of second unit pixels PX_201, PX_202, PX_203, and PX_204 are described as a plurality of second unit pixels PX_201-PX_204.

In the third sub-pixel group G3, the plurality of third unit pixels PX_301, PX_302, PX_303, and PX_304 may overlap one second micro lens ML2. The plurality of third unit pixels PX_301, PX_302, PX_303, and PX_304 may be arranged in 2×2, and each plurality of third unit pixels PX_301, PX_302, PX_303, and PX_304 may include a color filter of green (G). That is, the second sub-pixel group G2 and the third sub-pixel group G3 including the same type of the color filter may include the same type of the second micro lens ML2. Hereinafter, the plurality of third unit pixels PX_301, PX_302, PX_303, and PX_304 are described as a plurality of third unit pixels PX_301-PX_304.

In the fourth sub-pixel group G4, the plurality of fourth unit pixels PX_401, PX_402, PX_403, and PX_404 may overlap a third micro lens ML3. A plurality of fourth unit pixels PX_401, PX_402, PX_403, and PX_404 may be arranged in 2×2, and each plurality of fourth unit pixels PX_401, PX_402, PX_403, and PX_404 may include a color filter of blue (B). Hereinafter, the plurality of fourth unit pixels PX_401, PX_402, PX_403, and PX_404 are referred to as the plurality of fourth unit pixels PX_401-PX_404.

Referring to FIG. 9 and FIG. 10, the first curvature of first micro lens ML1 is the largest, the second curvature of second micro lens ML2 is next largest, and the third curvature of third micro lens ML3 may be the smallest. In addition, the first dead zone DZ_R of the first micro lens ML1 is the largest, the second dead zone DZ_G of the second micro lens ML2 is the next largest, and the third dead zone DZ_B of the 3 microlens ML3 may have the smallest range. According to an embodiment, the first dead zone DZ_R of the first micro lens ML1 overlapping the red (R) color filter 303 may be the largest, the second dead zone DZ_G corresponding to the second micro lens ML2 overlapping the green (G) color filter 303 may be the next largest, and the third dead zone DZ_B corresponding to the third micro lens ML3 overlapping the blue (B) color filter 303 may be the smallest (DZ_R>DZ_G>DZ_B).

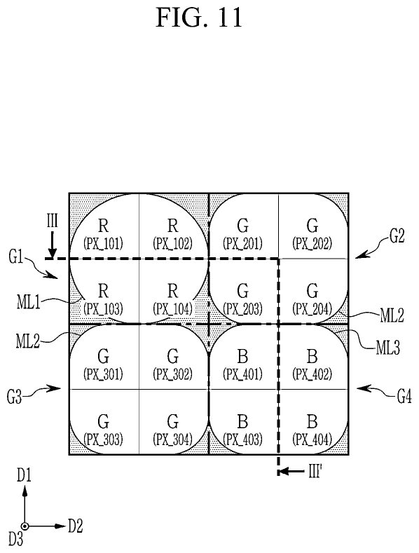

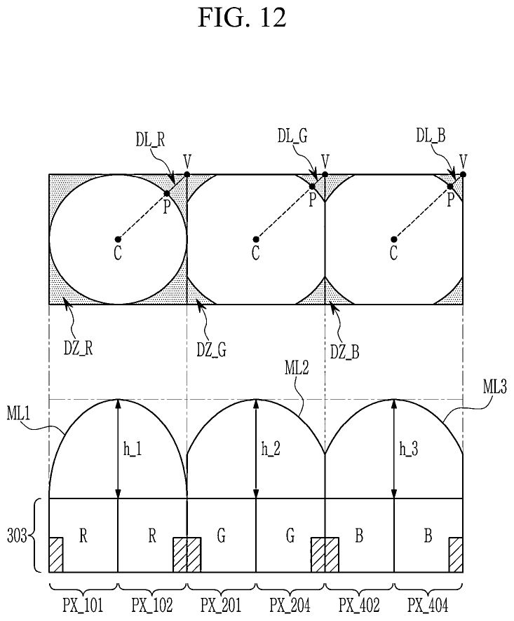

FIG. 11 is an enlarged plan view of an area M of FIG. 3, illustrating an example of a sub-pixel group including unit pixels arranged in a 2×2 form based on a color filter RGGB according to one or more embodiments. FIG. 12 is a cross-sectional view taken along a line III-III′ of FIG. 11 according to one or more embodiments.

In FIG. 11 and FIG. 12, the plurality of unit pixels included in each of the first sub-pixel group G1, the second sub-pixel group G2, the third sub-pixel group G3, and the fourth sub-pixel group G4, the arrangement of the plurality of unit pixels, and the kind of the color filter 303 are similar as these shown in FIG. 9 and FIG. 10, and repeated descriptions may be omitted.

In FIGS. 9 and 10, the first micro lens ML1, the second micro lens ML2, and the third micro lens ML3 were configured so that the first dead zone DZ_R had the largest size, the second dead zone DZ_G had the next largest size, and the third dead zone DZ_B had the smallest range (DZ_R>DZ_G>DZ_B). On the other hand, in FIGS. 11 and 12, the first micro lens ML1, the second micro lens ML2, and the third micro lens ML3 may be configured so that the sizes of the second dead zone DZ_G and the third dead zone DZ_B are substantially the same, and the size of the second dead zone DZ_G and the third dead zone DZ_B is smaller than the first dead zone DZ_R (DZ_R>DZ_G=DZ_B).

According to an embodiment, the sizes of the green (G) second dead zone DZ_G corresponding to second micro lens ML2 overlapping color filter 303 and the third dead zone DZ_B corresponding to the third micro lens ML3 overlapping blue (B) color filter 303 may substantially the same (DZ_G=DZ_B), and the second dead zone DZ_G and the third dead zone DZ_B may be smaller than the first dead zone DZ_R of the first micro lens ML1 overlapping the red (R) color filter 303 (DZ_R>DZ_G=DZ_B).

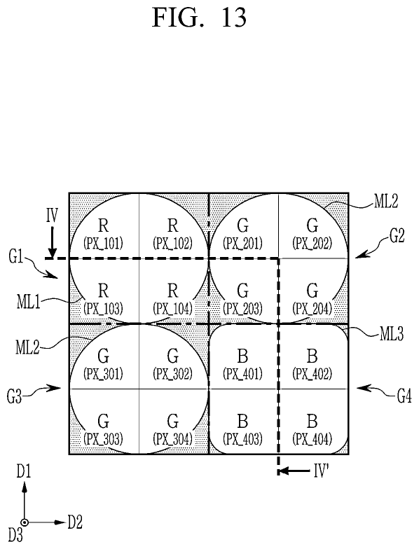

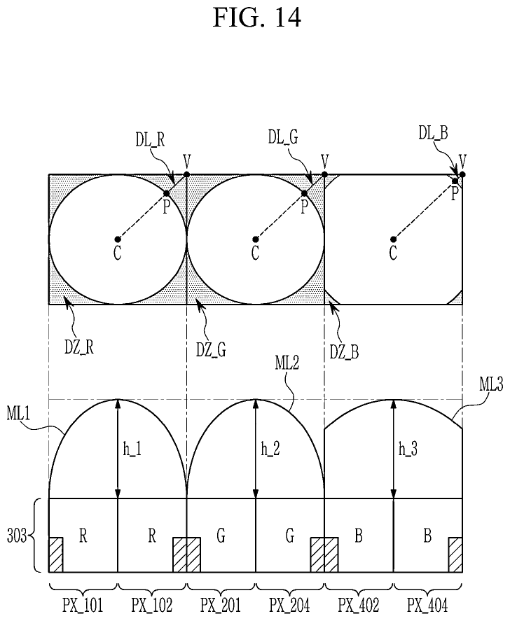

FIG. 13 is an enlarged plan view of an area M of FIG. 3, illustrating an example of a sub-pixel group including unit pixels arranged in a 2×2 form based on a color filter RGGB according to one or more embodiments. FIG. 14 is a cross-sectional view taken along a line IV-IV′ of FIG. 13 according to one or more embodiments.

In FIG. 13 and FIG. 14, the plurality of unit pixels included in each of the first sub-pixel group G1, the second sub-pixel group G2, the third sub-pixel group G3, and the fourth sub-pixel group G4, the arrangement of the plurality of unit pixels, and the kind of the color filter 303 are similar as these shown in FIG. 9 and FIG. 10, and repeated descriptions may be omitted.

The first micro lens ML1, the second micro lens ML2, and the third micro lens ML3 may be configured so that the sizes of the first dead zone DZ_R and the second dead zone DZ_G are the substantially same, and the sizes of the first dead zone DZ_R and the second dead zone DZ_G is larger than the size of the third dead zone DZ_B (DZ_R=DZ_G>DZ_B).

According to an embodiment, the second dead zone DZ_G may be smaller than the first dead zone DZ_R and larger than the third dead zone DZ_B (DZ_R>DZ_G>DZ_B). According to another embodiment, two sizes among the first dead zone DZ_R, the second dead zone DZ_G, and the third dead zone DZ_B may be substantially the same (e.g., DZ_R=DZ_G>DZ_B, or DZ_R>DZ_G=DZ_B). At least one among the sizes of the first dead zone DZ_R, the second dead zone DZ_G, and the third dead zone DZ_B is not same.

According to an embodiment, when assuming that the size of the third dead zone DZ_B is 100%, the size of the first dead zone DZ_R may belong to a range of 100% or more and less than 800%, and the size of the second dead zone DZ_G may also belong to a range of 100% or more and less than 800%. However, even in this case, for example, like the first dead zone DZ_R of 200%, the second dead zone DZ_G of the 300%, and the third dead zone DZ_B of the 100%, so that an embodiment in which the second dead zone DZ_G is larger than the first dead zone DZ_R is not included.

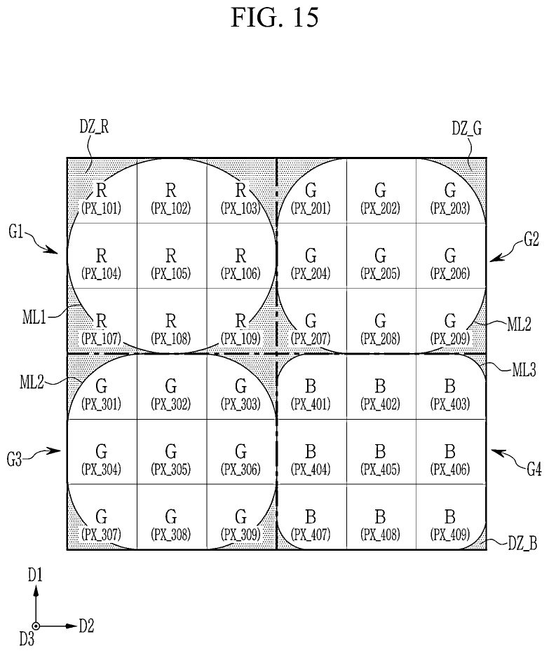

FIG. 15 to FIG. 17 are enlarged plan views of an area M of FIG. 3, illustrating various examples of a sub-pixel group including unit pixels arranged in a 3×3 form based on a color filter RGGB according to one or more embodiments.

Aspects shown in FIG. 15 to FIG. 17 may include similar aspects as those shown above, and repeated descriptions thereof may be omitted. As described above, each of the first to fourth sub-pixel groups G1, G2, G3, and G4 includes the plurality of unit pixels arranged in the 2×2 form in the first direction D1 and the second direction D2. In FIGS. 15 to 17, each of the first to fourth sub-pixel groups G1, G2, G3, and G4 may include a plurality of unit pixels arranged in a 3×3 form in the first direction D1 and the second direction D2.

That is, while one micro lens ML overlaps on four unit pixels arranged in the 2×2 form in previously described embodiments, in FIG. 15 to FIG. 17, one micro lens ML overlaps on nine unit pixels arranged in the 3×3 form.

Referring to FIG. 15, the first dead zone DZ_R may have the largest range, the second dead zone DZ_G may have the next largest range, and the third dead zone DZ_B may have the smallest range. Specifically, the second dead zone DZ_G corresponding to the second micro lens ML2 overlapping the green (G) color filter 303 may be smaller than the first dead zone DZ_R corresponding to the first micro lens ML1 overlapping the red (R) color filter 303, and larger than the third dead zone DZ_B corresponding to the third micro lens ML3 overlapping the blue (B) color filter 303 (DZ_R>DZ_G>DZ_B).

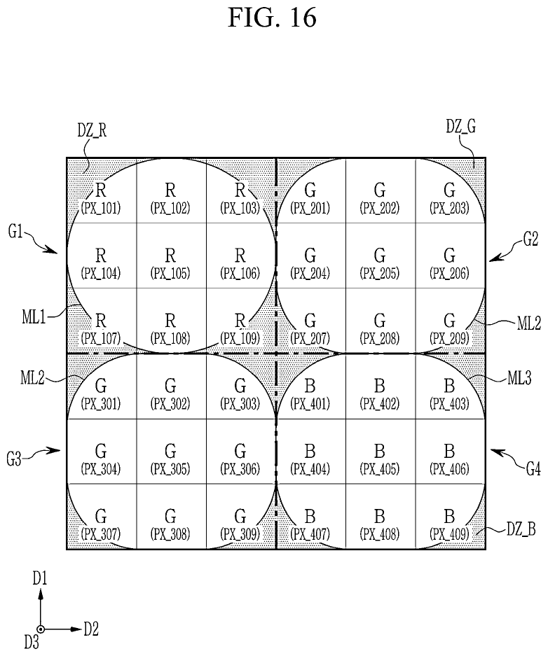

Referring to FIG. 16, the sizes of the second dead zone DZ_G corresponding to the second micro lens ML2 overlapping the green (G) color filter 303 and the third dead zone DZ_R corresponding to the third micro lens ML3 overlapping the blue (B) color filter 303 may be substantially the same size, and the second dead zone DZ_G and the third dead zone DZ_B may be smaller than the first dead zone DZ_R corresponding to the first micro lens ML1 overlapping the red (R) color filter 303 (DZ_R>DZ_G=DZ_B).

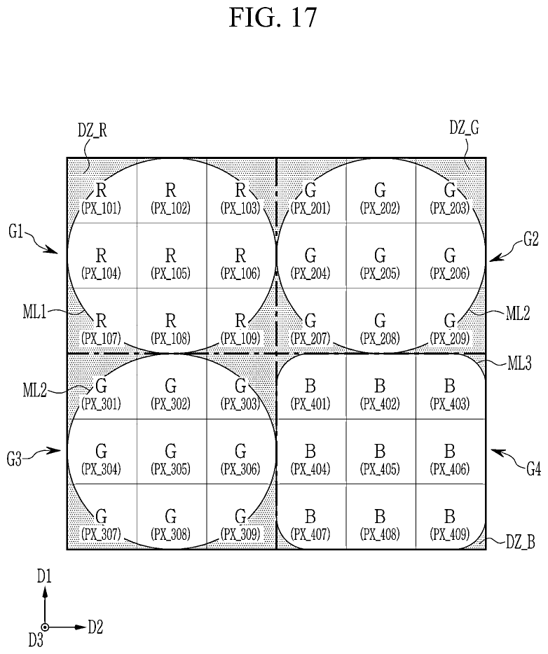

Referring to FIG. 17, the sizes of the first dead zone DZ_R corresponding to the first micro lens ML1 overlapping the red (R) color filter 303 and the second dead zone DZ_G corresponding to the second micro lens ML2 overlapping green (G) color filter 303 may be substantially the same, and the first dead zone DZ_R and the second dead zone DZ_G may be smaller than the third dead zone DZ_R corresponding to the third micro lens ML3 overlapping the blue (B) color filter 303 (DZ_R=DZ_G>DZ_B).

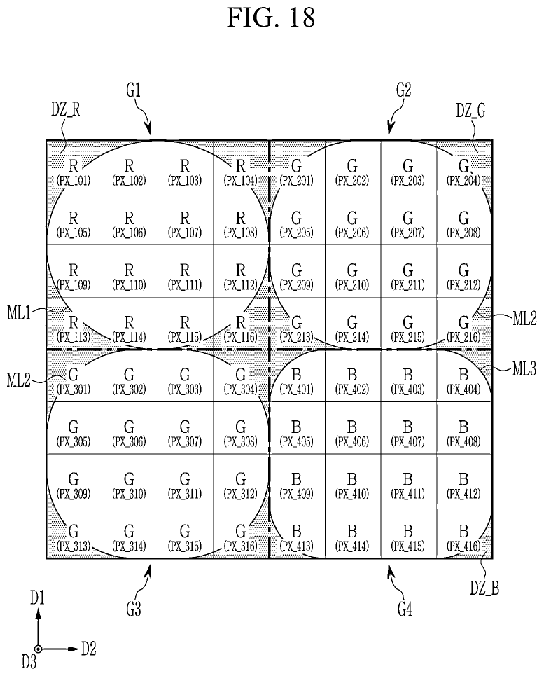

FIG. 18 to FIG. 20 are enlarged plan views of an area M of FIG. 3, illustrating various examples of a sub-pixel group including unit pixels arranged in a 4×4 form based on a color filter RGGB according to one or more embodiments.

Aspects shown in FIG. 18 to FIG. 20 may include similar aspects as those shown above, and repeated descriptions thereof may be omitted. In FIGS. 15 to 17, each of the first to fourth sub-pixel groups G1, G2, G3, and G4 includes the plurality of unit pixels arranged in the 3×3 form in the first direction D1 and the second direction D2. In FIGS. 18 to 20, each of the first to fourth sub-pixel groups G1, G2, G3, and G4 may include a plurality of unit pixels arranged in a 4×4 form in the first direction D1 and the second direction D2.

That is, in the embodiment shown in FIG. 15 to FIG. 17, one micro lens ML overlaps on nine unit pixels arranged in the 3×3 form, whereas in the embodiment shown in FIG. 18 to FIG. 20, one micro lens ML overlaps on sixteen unit pixels arranged in the 4×4 form.

Referring to FIG. 18, the first dead zone DZ_R may have the largest range, the second dead zone DZ_G may have the next largest range, and the third dead zone DZ_B may have the smallest range. Specifically, the second dead zone DZ_G corresponding to the second micro lens ML2 overlapping the green (G) color filter 303 may be smaller than the first dead zone DZ_R corresponding to the first micro lens ML1 overlapping the red (R) color filter 303, and larger than the third dead zone DZ_B corresponding to the third micro lens ML3 overlapping the blue (B) color filter 303 (DZ_R>DZ_G>DZ_B).

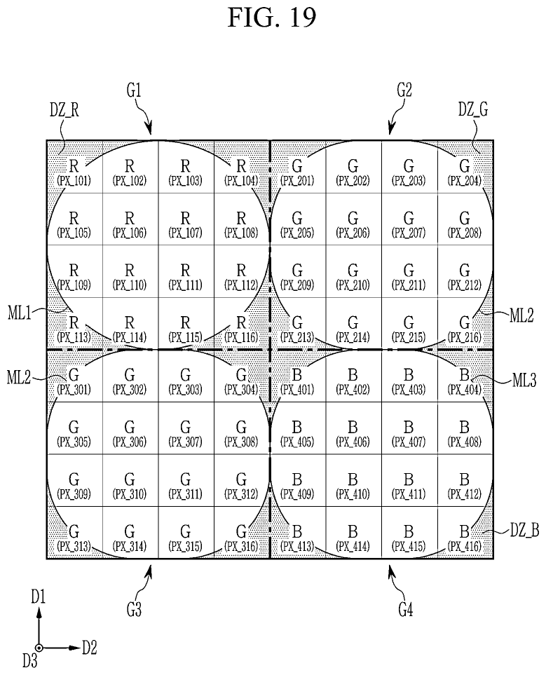

Referring to FIG. 19, the sizes of the second dead zone DZ_G corresponding to the second micro lens ML2 overlapping the green (G) color filter 303 and the third dead zone DZ_R corresponding to the third micro lens ML3 overlapping the blue (B) color filter 303 may be substantially the same, and the second dead zone DZ_G and the third dead zone DZ_R may be smaller than the first dead zone DZ_R corresponding to the first micro lens ML1 overlapping the red (R) color filter 303 (DZ_R>DZ_G=DZ_B).

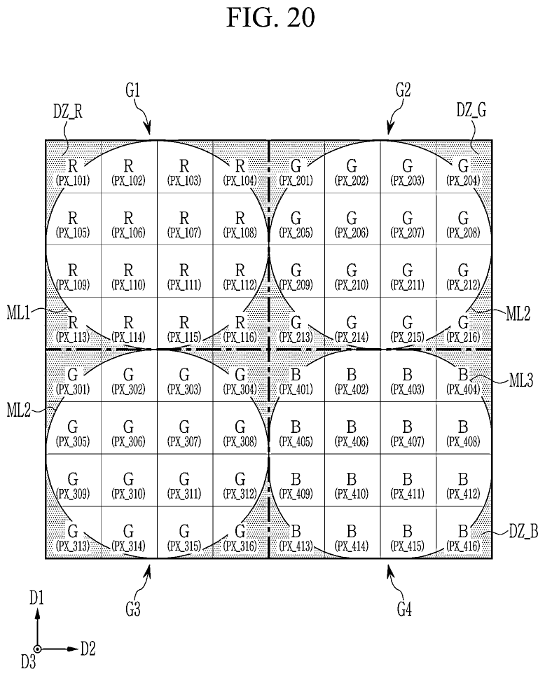

Referring to FIG. 20, the sizes of the first dead zone DZ_R corresponding to the first micro lens ML1 overlapping the red (R) color filter 303 and the second dead zone DZ_G corresponding to the second micro lens ML2 overlapping the green (G) color filter 303 may be substantially the same, and the first dead zone DZ_R and the second dead zone DZ_G may be greater than the third dead zone DZ_R corresponding to the third micro lens ML3 overlapping the blue (B) color filter 303 (DZ_R=DZ_G>DZ_B).

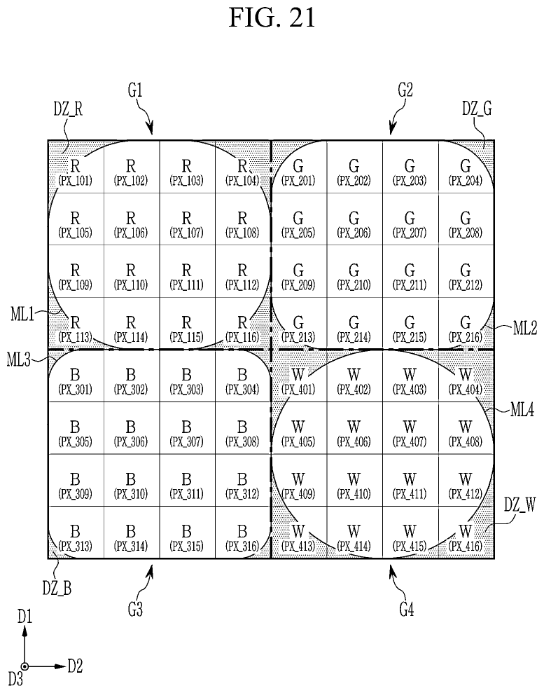

FIG. 21 to FIG. 23 are enlarged plan views of an area M of FIG. 3, illustrating various examples of a sub-pixel group including unit pixels arranged in a 4×4 form based on a color filter RGBW according to one or more embodiments.

Aspects shown in FIG. 21 to FIG. 23 may include similar aspects as those shown above, and repeated descriptions thereof may be omitted. As described above, each of a plurality of third unit pixels PX_301 to PX_316 included in the third sub-pixel group G3 includes the green (G) color filter 303. In FIGS. 21 to 23, each of the plurality of third unit pixels PX_301 to PX_316 included in the third sub-pixel group G3 may include the blue (B) color filter 303. Also, in the previously described embodiments, each of the plurality of fourth unit pixels PX_401 to PX_416 included in the fourth sub-pixel group G4 may include the blue (B) color filter. In FIGS. 21 to 23, each of the plurality of fourth unit pixels PX_401 to PX_416 included in the fourth sub-pixel group G4 may include a white (W) color filter.

Referring to FIG. 21, according to an embodiment, the fourth dead zone DZ_W corresponding to the fourth micro lens ML4 overlapping the fourth sub-pixel group G4 may be the largest, and the first dead zone DZ_R, the second dead zone DZ_G, and the third dead zone DZ_B may be sequentially larger (DZ_W>DZ_R>DZ_G>DZ_B).

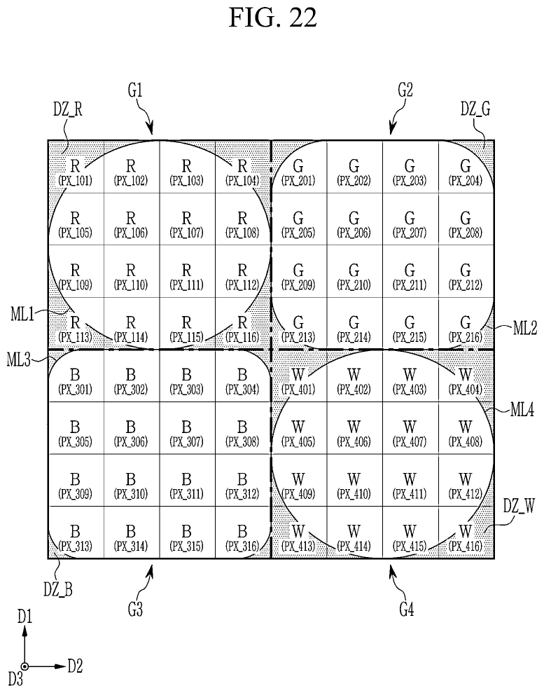

Referring to FIG. 22, according to an embodiment, the sizes of the fourth dead zone DZ_W and the first dead zone DZ_R may be the same, the sizes of the fourth dead zone DZ_W and the first dead zone DZ_R may be the largest, and the second dead zone DZ_G and third dead zone DZ_B may be sequentially larger (DZ_W=DZ_R>DZ_G>DZ_B).

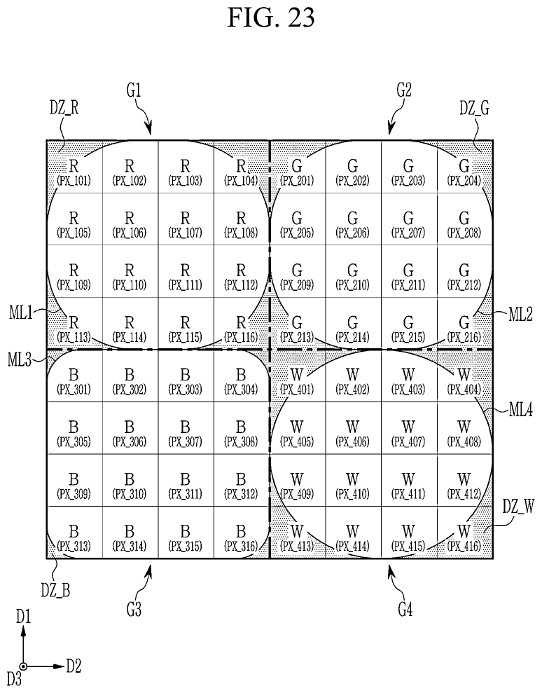

Referring to FIG. 23, according to an embodiment, the sizes of the first dead zone DZ_R and the second dead zone DZ_G may be substantially the same, and the first dead zone DZ_R and the second dead zone DZ_G may be smaller than the fourth dead zone DZ_W and larger than the third dead zone DZ_B (DZ_W>DZ_R=DZ_G>DZ_B).

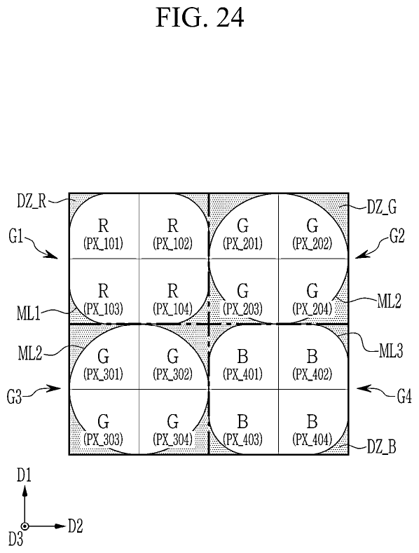

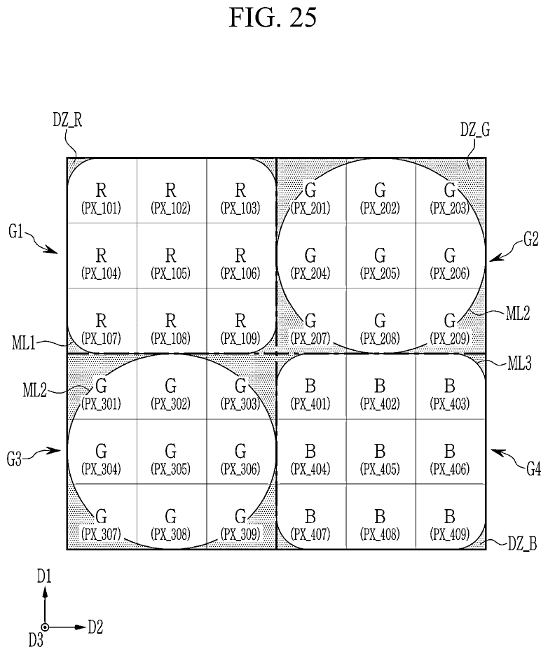

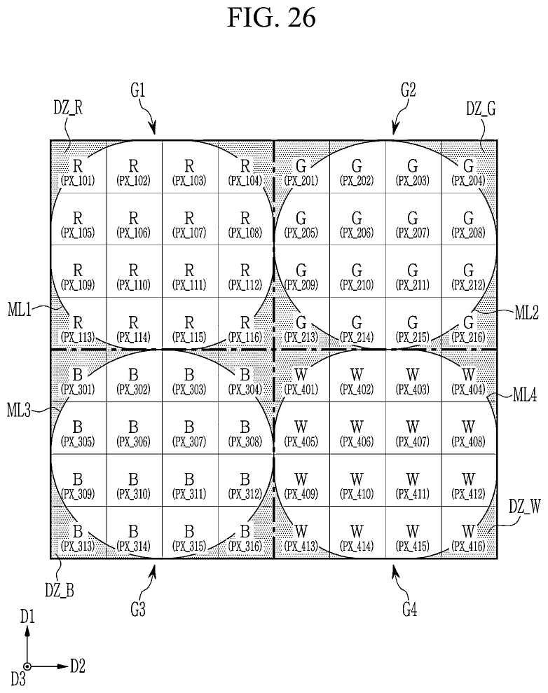

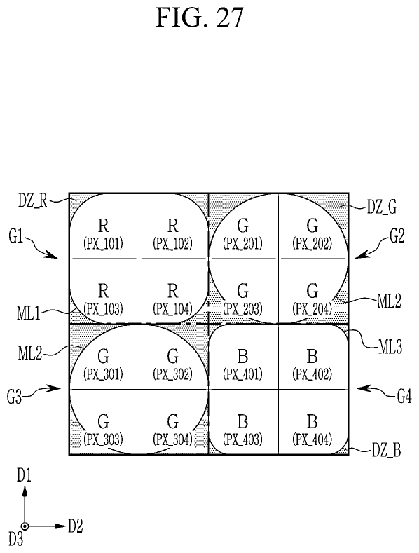

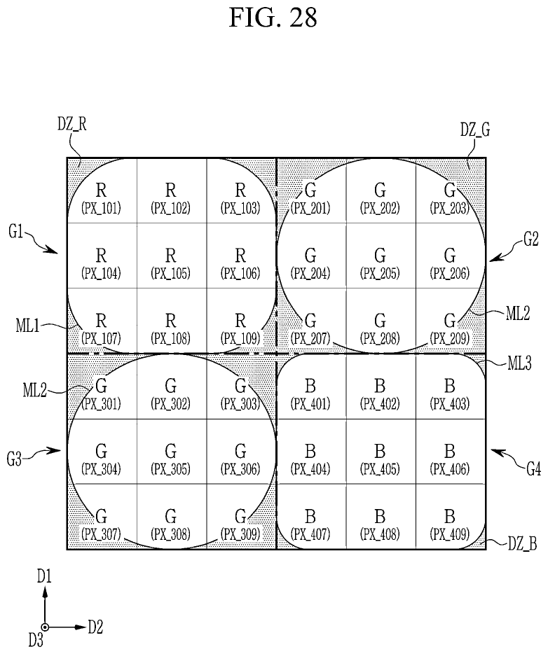

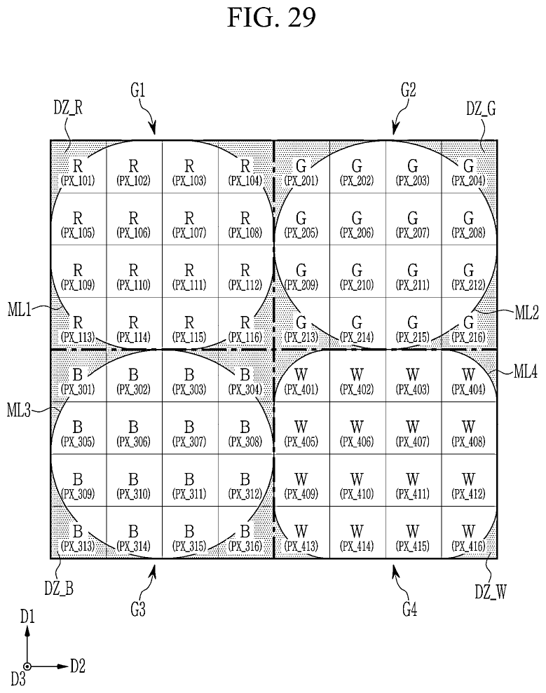

FIG. 24 to FIG. 26 are diagrams illustrating various examples for a sub-pixel group according to one or more embodiments. FIG. 27 to FIG. 29 are diagrams illustrating various examples for a sub-pixel group according to one or more embodiments.

In FIG. 24 to FIG. 29, the plurality of unit pixels included in each of the first sub-pixel group G1, the second sub-pixel group G2, the third sub-pixel group G3, and the fourth sub-pixel group G4, the arrangement of the plurality of unit pixels, and the kind of the color filter 303 are similar as these shown in FIG. 9 to FIG. 20, and repeated descriptions may be omitted.

Referring to FIG. 24 to FIG. 26, the first micro lens ML1, the second micro lens ML2, and the third micro lens ML3 may be configured so that the size of the second dead zone DZ_G is the largest, and the sizes of the first dead zone DZ_R and the third dead zone DZ_B are substantially the same (DZ_G>DZ_R=DZ_B).

Referring to FIG. 27 to FIG. 29, the first micro lens ML1, the second micro lens ML2, and the third micro lens ML3 may be configured so that the size of the second dead zone DZ_G is the largest, the first dead zone DZ_R is the next largest, and the third dead zone DZ_B is the smallest (DZ_G>DZ_R>DZ_B).

Example embodiments the disclosure may improve an image quality of the image sensor by preventing light passing through the micro lens from entering other adjacent pixels.

Example embodiments of the disclosure may improve a convenience on a design of the image sensor by having the same focal point regardless of the type of incident light.

At least one of the devices, units, components, modules, units, or the like represented by a block or an equivalent indication in the above embodiments including, but not limited to, FIG. 1, may be physically implemented by analog and/or digital circuits including one or more of a logic gate, an integrated circuit, a microprocessor, a microcontroller, a memory circuit, a passive electronic component, an active electronic component, an optical component, and the like, and may also be implemented by or driven by software and/or firmware (configured to perform the functions or operations described herein).

Each of the embodiments provided in the above description is not excluded from being associated with one or more features of another example or another embodiment also provided herein or not provided herein but consistent with the disclosure.

While the disclosure has been particularly shown and described with reference to embodiments thereof, it will be understood that various changes in form and details may be made therein without departing from the spirit and scope of the following claims.

What is claimed is:

1. An image sensor comprising:
a first sub-pixel group comprising a plurality of first unit pixels;
a first color filter;
a first micro lens at least partially overlapping the plurality of first unit pixels;
a second sub-pixel group comprising a plurality of second unit pixels;
a second color filter;
a second micro lens at least partially overlapping the plurality of second unit pixels;
a third sub-pixel group comprising a plurality of third unit pixels;
a third color filter;
a third micro lens at least partially overlapping the plurality of third unit pixels,
a first dead zone in which the first micro lens does not overlap the first sub-pixel group;
a second dead zone in which the second micro lens does not overlap the second sub-pixel group; and
a third dead zone in which the third micro lens does not overlap the third sub-pixel group,
wherein a height of the first micro lens, a height of the second micro lens, and a height of the third micro lens are substantially the same, and
wherein at least one of a size of the first dead zone, a size of the second dead zone, and a size of the third dead zone is different from at least one of the other of the size of the first dead zone, the size of the second dead zone, and the size of the third dead zone.

2. The image sensor of claim 1, wherein the first color filter comprises a red (R) filter,
wherein the second color filter comprises a green (G) filter, and
wherein the third color filter comprises a blue (B) filter.

3. The image sensor of claim 2, wherein the size of the second dead zone is smaller than the size of the first dead zone and larger than the size of the third dead zone.

4. The image sensor of claim 3, wherein each of the size of the first dead zone and the size of the second dead zone is at least 100% and less than 800% of the size of the third dead zone.

5. The image sensor of claim 3, further comprising:
a fourth sub-pixel group comprising a plurality of fourth unit pixels;
a white (W) fourth color filter and a fourth micro lens at least partially overlapping the plurality of fourth unit pixels; and
a fourth dead zone in which the fourth micro lens does not overlap the fourth sub-pixel group,
wherein at least one of the size of the first dead zone, the size of the second dead zone, the size of the third dead zone, and a size of the fourth dead zone is different.

6. The image sensor of claim 5, wherein the fourth dead zone is larger than the third dead zone.

7. The image sensor of claim 5, wherein each of the plurality of first unit pixels, the plurality of second unit pixels, the plurality of third unit pixels, and the plurality of fourth unit pixels is in a 2×2 arrangement in a first direction parallel to a first surface of a substrate and a second direction parallel to the first surface and perpendicular to the first direction.

8. The image sensor of claim 5, wherein each of the plurality of first unit pixels, the plurality of second unit pixels, the plurality of third unit pixels, and the plurality of fourth unit pixels is in a 3×3 arrangement in a third direction parallel to a first surface of a substrate and in a fourth direction perpendicular to the third direction.

9. The image sensor of claim 5, wherein each of the plurality of first unit pixels, the plurality of second unit pixels, the plurality of third unit pixels, and the plurality of fourth unit pixels is in a 4×4 arrangement in a fifth direction parallel to a first surface of a substrate and in a sixth direction perpendicular to the fifth direction.

10. The image sensor of claim 5, further comprising:
a pixel isolation pattern in a seventh direction perpendicular a first surface of a substrate between the plurality of first unit pixels, the plurality of second unit pixels, the plurality of third unit pixels, and the plurality of fourth unit pixels, respectively.

11. The image sensor of claim 10, wherein the pixel isolation pattern is vertically recessed from the first surface of the substrate to a second surface of the substrate such that the pixel isolation pattern penetrates the substrate.

12. The image sensor of claim 10, wherein the pixel isolation pattern is recessed vertically in an eighth direction from a second surface of the substrate to the first surface of the substrate and is spaced apart from the first surface of the substrate by a predetermined interval.

13. An image sensor comprising:
a substrate;
a plurality of photodiodes in the substrate, the plurality of photodiodes comprising a first photodiode, a second photodiode and a third photodiode;
a first sub-pixel group comprising a plurality of first unit pixels;
a first color filter on the first photodiode;
a first micro lens at least partially overlapping the plurality of first unit pixels;
a second sub-pixel group comprising a plurality of second unit pixels;
a second color filter on the second photodiode;
a second micro lens at least partially overlapping the plurality of second unit pixels;
a third sub-pixel group comprising a plurality of third unit pixels;
a third color filter on the third photodiode;
a third micro lens overlapping the plurality of third unit pixels;
a first dead zone in which the first micro lens does not overlap the first sub-pixel group;
a second dead zone in which the second micro lens does not overlap the second sub-pixel group; and
a third dead zone in which the third micro lens does not overlap the third sub-pixel group,
wherein a height of the first micro lens, a height of the second micro lens, and a height of the third micro lens are substantially the same, and
wherein at least one of a size of the first dead zone, a size of the second dead zone, and a size of the third dead zone is different from at least one of the other of the size of the first dead zone, the size of the second dead zone, and the size of the third dead zone.

14. The image sensor of claim 13, wherein the first color filter comprises a red (R) filter,
wherein the second color filter comprises a green (G) filter, and
wherein the third color filter comprises a blue (B) filter.

15. The image sensor of claim 14, wherein the size of the second dead zone is smaller than the size of the first dead zone and larger than the size of the third dead zone.

16. The image sensor of claim 14, wherein each of the size of the first dead zone and the size of the second dead zone is at least 100% or more and less than 800% of the size of the third dead zone.

17. An image sensor comprising:
a substrate;
a plurality of photodiodes in the substrate, the plurality of photodiodes comprising a first photodiode, a second photodiode, a third photodiode, and a fourth photodiode;
a first sub-pixel group comprising a plurality of first unit pixels;
a first color filter on the first photodiode;
a first micro lens at least partially overlapping the plurality of first unit pixels;
a second sub-pixel group comprising a plurality of second unit pixels;
a second color filter on the second photodiode;
a second micro lens at least partially overlapping the plurality of second unit pixels;
a third sub-pixel group comprising a plurality of third unit pixels;
a third color filter on the third photodiode;
a third micro lens at least partially overlapping the plurality of third unit pixels;
a fourth sub-pixel group comprising a plurality of fourth unit pixels;
a fourth color filter on the fourth photodiode;
a fourth micro lens at least partially overlapping the plurality of fourth unit pixels;
a first dead zone in which the first micro lens does not overlap the first sub-pixel group;
a second dead zone in which the second micro lens does not overlap the second sub-pixel group;
a third dead zone in which the third micro lens does not overlap the third sub-pixel group; and
a fourth dead zone in which the fourth micro lens does not overlap the fourth sub-pixel group,
wherein a height of the first micro lens, a height of the second micro lens, a height of the third micro lens, and a height of the fourth micro lens are substantially the same, and
wherein at least one of a size of the first dead zone, a size of the second dead zone, a size of the third dead zone, and a size of the fourth dead zone is different from at least one of the other of the size of the first dead zone, the size of the second dead zone, the size of the third dead zone, and the size of the fourth dead zone.

18. The image sensor of claim 17, wherein the first color filter comprises a red (R) filter,
wherein the second color filter comprises a green (G) filter,
wherein the third color filter comprises a blue (B) filter, and
wherein the fourth color filter comprises a white (W) filter.

19. The image sensor of claim 17, wherein the size of the second dead zone is smaller than the size of the first dead zone and larger than the size of the third dead zone, and
wherein the size of the fourth dead zone is larger than the size of the first dead zone.

20. The image sensor of claim 17, further comprising:
a pixel isolation pattern between the plurality of first unit pixels, the plurality of second unit pixels, the plurality of third unit pixels, and the plurality of fourth unit pixels,
wherein the pixel isolation pattern is vertically recessed from a first surface of the substrate to a second surface of the substrate such that the pixel isolation pattern penetrates the substrate.
